(19) United States
(12) Patent Application Publication
(10) Pub. No.: US 2004/0060519 A1
(43) Pub. Date: Apr. 1, 2004

(54) Quartz to quartz seal using expanded PTFE gasket material

(75) Inventors: David A. Beauchaine, Vancouver, WA (US); Aaron S. Newton, Vancouver, WA (US); Mike Tabor, Vancouver, WA (US)

Correspondence Address: OLIFF & BERRIDGE, PLC, P.O. BOX 19928, ALEXANDRIA, VA, 22320, US

(73) Assignee: SEH AMERICA INC., Vancouver, WA

(21) Appl. No.: 10/260,268

(22) Filed: Oct. 1, 2002

(51) Int. Cl. C23C 16/00

(52) U.S. Cl. 118/724

(57) ABSTRACT

A gasket material made from expanded PTFE for sealing high purity semiconductor furnace operations is provided. The gasket may be used in place of O-rings made of fluoro-rubber or standard PTFE material. Gaskets made of expanded PTFE provide greater flexibility and thus gives a better seal than standard O-rings.

### BACKGROUND OF THE INVENTION

1. Field of Invention

The present invention is directed to the field of semiconductor wafer preparation and more particularly to a seal assembly for a vertical atmospheric thermal treatment apparatus.

2. Description of Related Art

In the process of manufacturing a semiconductor device, various kinds of heat-treating apparatuses may be used to carry out different treatment processes, such as oxidation, diffusion, chemical vapor deposition (CVD) and annealing. Some of these treatment processes require the proper control of the composition of the atmosphere during the treatment process. For example, some annealing processes are performed in inert gas atmospheres, such as nitrogen or argon, and certain oxidation processes may be performed under hydrogen steam or HCl.

Generally, the heat treatment processes may enocmpass normal pressure high temperature processes, e.g., a substantially atmospheric pressure and a high temperature of, e.g., about 1000° C. as well as low-pressure heat treatment processes, e.g., some Torr pressure at about 800° C. A heat treatment apparatus is selected on the basis of the kind of heat treatment to be conducted on particular types of semiconductor wafers. A normal pressure high temperature heat treatment apparatus is sometimes followed by a low-pressure heat treatment apparatus, which requires moving the wafers between the respective apparatuses. The reverse processing thereof is also conducted.

A typical heat treatment apparatus employs a vertically long process chamber for accommodating a wafer boat, in which a number of wafers are stacked for appropriate processing. The process chamber is generally constituted of a reaction tube made of quartz having a gas inlet and a gas outlet of it side wall. The reaction tube has a port at its bottom through which the wafer boat is loaded and unloaded to and from the reaction tube. Access to the port is generally through a quartz lid or door-tube assembly. Thus, the process chamber is made entirely of quartz to ensure that the process chamber is highly heat resistant and highly corrosion resistant. Of course, other apparatus configurations are also known in the art.

The regulation of atmospheric conditions in the process chamber requires adequate sealing at the quartz-to-quartz door assembly. The lack of a proper seal can result in the leaking of reactant gases past the door seal and into the surrounding framework, which can lead to the corrosion of the framework. A poor seal can also result in the leakage of ambient air into the process chamber, which can result in contamination or degradation of the silicon wafer surface.

Typically, the seals used at the connections between the quartz door assembly and the reaction vessel typically employ O-rings made of materials such as fluoro-rubber or thermoplastics such as TURCITE®, KALREZ® and VITON®. See U.S. Pat. No. 5,578,132 to Yamaga et al. Although conventional O-rings may be used in various high and low temperature applications, materials such as VITON® and KALREZ® are better suited to applications where a cooling channel can be provided, particularly in high temperature applications. However, in high temperature applications where a cooling channel cannot be provided, the temperature resistance of these materials is generally poor and leads to the problem of out gassing, described below. In addition, conventional O-ring seals generally exhibit poor sealing performance. Such poor performance characteristics can be attributed to the material of the O-rings being too hard, which reduces the ability of the seal to conform to surfaces with minor imperfections. Alternatively, the rings may simply allow the gas atmosphere to leak out during high temperature thermal processing. This inevitably results in the contamination of the wafers treated in the vessel.

Additional problems with such seals include, for example, low tolerance for high temperatures. Conventional fluoro-rubber O-rings can generally tolerate temperatures up to about 200° C.; thus, when the temperature exceeds this limit, the O-rings melt and deform, and can no longer maintain an adequate seal. When operating temperatures are expected to exceed these limits of about 200° C., then various cooling methods must be employed to prevent melting of the O-ring seals. Such cooling is disclosed in, for example, U.S. Pat. No. 5,578,132. Once melted, removal of the O-rings for replacement is often difficult. Gas and water components present in fluoro-rubber or silicone-rubber O-rings may also be released during use (known as out-gassing) particularly at high temperatures. Often, such discharge from the O-rings introduces contaminants into the treatment chamber, which can lead to large differences between processing lots of the objects being processed. See U.S. Pat. No. 5,368,648 to Sekizuka. After out-gassing occurs, the entire process load is usually ruined and the process of cleaning the system results in significant down-time.

Since its discovery over sixty years ago, polytetrafluoroethylene (PTFE) has become a popular material that has found widespread use in various applications. PTFE is known to be highly resistant to oxidation and reaction with chemicals, although halogenated solvents at high temperatures and pressures have been shown to have some adverse effect. Because of its superior heat and chemical resistant properties, PTFE is used to make a variety of products, including gaskets, liners, seals, flexible hose, coatings in aerospace applications, insulators, bearings, seals, piston rings and perhaps most notably, anti-stick coatings for cooking vessels.

As a gasket, PTFE has exhibited utility as a material for use in harsh chemical environments, which normally degrade many conventional metals, elastomers, and polymeric materials. Conventional, full density PTFE has a usable temperature range from as high as 260° C. to as low as near −273° C. However, conventional non-porous PTFE gasket materials, which have been compression molded or extruded and then heated to a temperature above 345° C., exhibit poor mechanical properties, such as low tensile strength and low cold flow resistance. This limits or excludes the use of such materials in these applications requiring long-term resistance to creep.

Seals using PTFE materials have been employed, most notably in plumbing applications. However, such PTFE seals have not found use in high purity semiconductor furnace applications.

### SUMMARY OF THE INVENTION

In view of the problems associated with conventional seals and fluoro-rubber O-rings in semiconductor heat treatment apparatuses, the present invention provides a seal in which the drawbacks identified above are minimized, if not eliminated. In particular, the seal of the present invention forms a seal that is less prone to leakage both into and out of the apparatus.

An appropriate seal for the heating devices used in semiconductor processing may be made from PTFE and may be produced in an expanded porous form. Expanded polytetrafluoroethylene is of a higher strength than conventional PTFE, has the chemical inertness of conventional PTFE, and has an increased temperature range of up to 315° C. in service without requiring additional cooling processes.

Although conventional polytetrafluoroethylene (PTFE) has adequate durability, its tendency to experience compressive creep renders this material problematic as well. PTFE gaskets (virgin, filled or expanded) all exhibit varying degrees of compressive creep or flow. For example, in applications with metal-to-metal contact of the flanges in an O-ring joint flange, there is no mechanism for compensating for even a slight amount of creep. If the gasket creeps and, as a result, becomes thinner, there is no longer a counterforce being exerted by the gasket against the flanges. Leaking between the flanges thus results.

A PTFE sealing material can be produced with limited long-term creep by wrapping a core of elongated or expanded PTFE with a high strength film of expanded PTFE. The high strength film is resistant to deformation and stretching and serves to contain the PTFE core in place within a compressed gasket. This material has proven to be quite effective in sealing plate and frame heat exchangers—providing thermal and chemical protection, long-life and durability, and ease in replacement.

Accordingly, it is a primary purpose of the present invention to provide a gasket material for flange apparatus that provides an effective long-term seal under pressure, while being durable, chemical and thermal resistant, non-contaminating, and easy to install. In addition to its resistance to high temperature, the compressibility of expanded PTFE, which allows adequate sealing, and the cleanliness of the material, all contribute to a gasket made of expanded PTFE being a superior alternative to standard O-rings and the materials from which such standard O-rings are made. The advantages pf expanded PTFE gaskets are especially apparent in high temperature applications where a cooling channel is not or cannot be provided. Under such conditions, standard O-rings are prone to melting and outgassing. Such problems can be avoided with gaskets made of expanded PTFE.

### BRIEF DESCRIPTION OF THE DRAWINGS

Certain preferred embodiments of this invention will be described in detail, with reference to the following figures, in which:

FIG. 1 is a vertical sectional view of a vertical type of heat-treating apparatus to which an embodiment of the seal assembly is applied;

FIG. 2 is an enlarged partial sectional view of the heat treatment apparatus of FIG. 1 indicated by arrow A, showing an exemplary seal assembly of the present invention.

### DETAILED DESCRIPTION OF PREFERRED EMBODIMENTS

This invention provides heat treatment apparatuses having seal assemblies comprising an expanded PTFE gasket. The invention also contemplates a new method of sealing surface-to-surface interfaces, such as quartz-to-quartz surfaces, using such flat gaskets. The gaskets may also be used in semiconductor heat treatment apparatus constructed of other materials, for example, stainless steel, silicon carbide and single crystal or polycrystalline silicon. Instead of the typical circular cross-section of an O-ring, gaskets are typically flat. According to the present invention, expanded PTFE gaskets have been found to possess the required degree of cleanliness as well as flexibility to allow proper sealing of the quartz flanges. The use of gaskets made of expanded PTFE also prevents corrosion, and results in cleaner processing of the wafers.

According to the present invention, a gasket is provided that is made of expanded PTFE. The gasket is preferably flat, i.e., square in cross-section, rather than being circular in cross-section. The flat gasket of the claimed invention can thus be used as a replacement for conventional O-ring seals. Of course, the gaskets of the present invention are not limited to such a configuration, but can take any desirable shape and cross section to suit the desired application.

Further, the gasket of the claimed invention differs from conventional gaskets and O-rings in the materials from which it is formed. The present inventors have discovered that gaskets formed form expanded PTFE, rather than fluoro-rubbers used for conventional O-rings, provide the above described significant advantages over the prior art. Any expanded PTFE material may be used in the described applications. Suitable expanded PTFE may be obtained, for example, from manufacturers such as Teadit Inc. and W. L. Gore and Associates Inc.

In embodiments of the present invention, the gasket is preferably round, such as for fitting between tubular apparatus sections or for fitting in similarly-shaped round openings. However, the invention is not limited to the described shapes. Rather, it will be apparent that gaskets of any other desired shape can be formed, such as oval, square, rectangular, asymmetrical and the like. This is another advantage over circular cross-section O-rings.

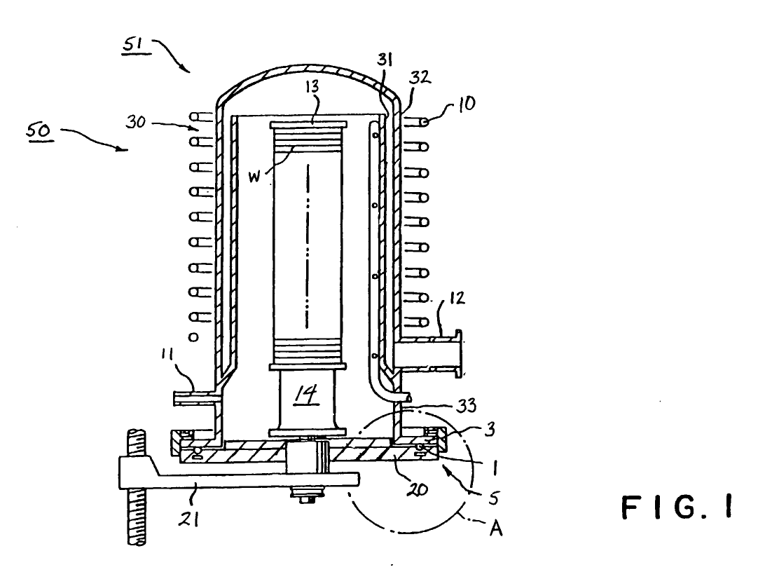

As shown in FIG. 1, a double-walled heating furnace 51 of the heat treatment apparatus 50 according to a first embodiment of the present invention comprises a processing vessel (processing chamber) 30 including an inner tube 31 of a heat resistant and corrosion resistant material, for example, such as quartz, having an opened and erected lower end, and an outer tube 32 also made of quartz disposed around the outer circumference of the inner tube 31 concentrically therewith at a certain interval. A heater 10 of a suitable type, for example a resistance-type heater, is wound around the outer circumference of the processing vessel 30. The bottom of the outer tube 32 is integrally connected with a cylindrical manifold 33 with a gas feed port II for introducing a processing gas into the processing vessel 30 and a gas exhaust port 12 for exhausting gas in the processing vessel 30. Specifically the manifold 33 is formed generally of the same material as the processing vessel 30 and has the gas feed port 11 and the gas exhaust port 12, also made of the same material, projected therefrom, with an open bottom and the bottom circumference formed in a bottom flange 3 for connection. Although FIG. 1 depicts a double-walled furnace, one skilled in the art would understand that the gasket may also be used with a single-walled apparatus.

The diameter of the manifold 34 is the same as that of the outer tube 32, and the manifold 34 and the outer tube 32 are glass-melted into one piece in fabrication. Then the quartz cylindrical inner tube 31 is accommodated in the outer tube 32 and the manifold 33 in one-piece. A lower end portion of the inner tube 31 is divergently expanded to be glass-melted onto the inside of the manifold 33 as described above. Thus the inner tube 31, the outer tubes 32 and the manifold 33 are formed of and connected integrally by a heat resistant and corrosion resistant material including, but not limited to quartz.

A wafer boat 13 made of, for example, quartz, is accommodated in the processing vessel 30 removably at the bottom thereof. A number of wafers W are held on the boat 13 longitudinally at a set pitch.

In a bottom opening of the manifold 33 a cap 20 is mounted on an arm 21 of lift means, such as elevator or other similar mechanism. The wafer boat 13 is mounted on the cap 20 through a quartz heat insulating cylinder 14. The cap 20 itself may also be made of quartz.

In this arrangement, it may be desirable to turn the wafer boat during processing to expose the wafers W evenly to a processing gas. Turning the boat thus assures greater intra-plane homogeneity of deposited films on the wafers W. A turning mechanism, such as the one described in, for example U.S. Pat. No. 5,578,132, may be used to turn the wafer boat during processing.

On the connection between the lower flange 3 of the manifold 33 and the peripheral edge of the cap 20 there is provided high temperature resistant seal means 5 whose sealing ability is not deteriorated even at a 1000° C. furnace temperature, and this permits high wafer boat during processing.

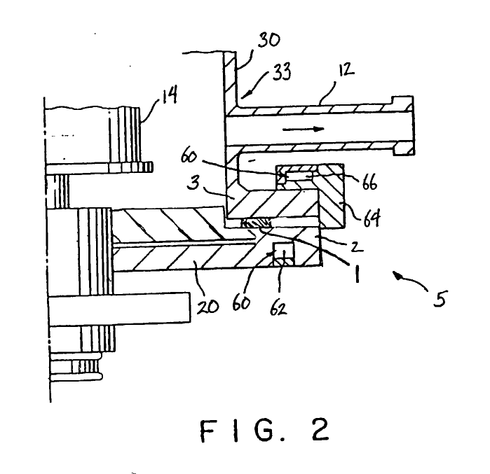

As shown in FIG. 2, the seal assembly 5 of the invention comprises a flange 2 formed in the peripheral edge of the cap 20, and a gasket 1 of expanded PTFE disposed on the flange 2. Although the expanded PTFE gasket 1 has improved sealing ability and heat resistance, it may be desirable to include a cooling mechanism to cool the gasket 1 when the furnace is used for high-temperature applications. Ordinarily, the temperatures to which the expaneded PTFE gasket 1 is exposed do not exceed the thermal tolerance of the gasket 1. This is due to the vertical arrangement of the furnace. The heat treatment process generally occurs in the upper portion of the furnace, thus, the location of the gasket 1 at the bottom of the processing chamber is generally sufficient to prevent the exposure of the gasket 1 to excessive heat.

Nonetheless, the seal assembly may include a cooling mechanism to cool the gaskets in furnaces that a regularly used for high temperature treatments. Thus, FIG. 2 also shows an exemplary cooling mechanism that may be included to provide adequate cooling for the expanded PTFE gasket 1. An exemplary cooling mechanism 60 includes a first cooling water passage 62 formed in a ring circumferentially in the cap 20, and a second cooling water passage 66 formed in a ring in a holding member 64 for holding the lower flange 3 of the manifold 33.

During the beat treatment process, the cap 20 and the exhaust port are heated to very high temperatures, but the gasket 1 in the cap 20 is cooled by passing cooling water through the cooling water passages 62, 66, so that the gasket 1 is efficiently cooled. Thus, damage to the gasket due to excessive heat is avoided, and the effectiveness of the seal is not compromised.

Although the invention has been described with reference to the embodiment of FIGS. 1 and 2, the description is exemplary only and is not limited thereto. Rather the gasket material of the present invention can be used in a wide range of processing apparatus, including but not limited to the various apparatus used in the treatment and processing of silicon crystal wafers.

A flat gasket seal made of expanded PTFE will provide a more effective seal in atmospheric vertical furnace processes, such as oxidation or annealing, in inert gasses, for example, such as nitrogen or argon. The tighter seal not only minimizes the potential for contamination of wafers processed, but also the corrosion of the structure surrounding the reaction vessel when the heat treatment utilizes corrosive gases or other reactive atmospheres, such as hydrogen steam, HCl or when using a Trans LC bubbler.

The gasket itself may be made from a sheet of expanded PTFE material. The thickness of the gasket may be varied as necessary, depending on the particular needs of the application. Generally the thickness of the gasket will depend upon the process tool used and the width of the gap to be filled. In the case of an annealing furnace, for example, gaskets of ⅛ to ¼ of an inch may be used. It is also acceptable to use multiple gaskets by stacking the gaskets together. The inside and outside diameter dimensions may also be changed, depending on the dimensions of the applications in which the gasket is used. For example, the inner diameter may be between 8 to 12 inches and the outer diameter may be between 9 to 13 inches. The width of the gasket material should be at least about ¾ of an inch. Of course, these dimensions are exemplary only, and are not limiting of the present invention.

### EXAMPLES

The effectiveness of the seal may be determined using the procedures established by the manufacturer or user of the furnace or other apparatus. Although the exact procedure may vary between manufacturers and models, the effectiveness of the seal may nonetheless be determined by whatever means appropriate. For example, the integrity of the door seal for a SVG VTR 7000 furnace is evaluated using the following protocol, as set forth in the maintenance manual.

A TEFLON union is disconnected from a quartz exhaust elbow on the rear of the VTR 7000 and a 10-foot long section of ¼ inch TYGON tubing is connected to the end of the elbow using a second TEFLON union. The tubing is then draped into a U-shaped manometer.

Both ends of the tubing are then secured to the side of the VTR 7000. The tubing is then evenly filled to about mid-level with water on both sides of the U. The water level in the tubing is monitored as 1 slpm of N₂ is flowed into the process tube. The flow is continued for approximately 20 seconds.

As the N₂ is flowing, the water levels on the two sides of the tube should be approximately 12 inches from one another. The N₂ flow is then shut off after 20 seconds and the amount of time required for the two water levels to return to equilibrium is measured. Generally, equilibrium should be re-established within 15 to 20 seconds. Equilibrium between the two levels will be restored in less time in the presence of a leak in the system. In contrast, it will take more time for equilibrium to be reestablished when a tight seal is present in the system.

The verification of process door seal integrity as described above (following the procedure according to the furnace maintenance manual) is performed to determine the door seal integrity. The following results are obtained:

TABLE I

| | | Water | | |
|---|---|---|---|---|
| | | Level | | |
| Test | | (Spec: | Leak Back Rate | Temper- |
| No. | Seal Material | >12″) | (Spec: >15-20 sec) | ature |
| 1 | Silicone rubber | 30″ | >5 min | Room |
| | | | | temp. |
| 2 | TEFLON/TURCITE | 6-8″ | 5 seconds | 800° C. |
| | (stock O-ring material) | | | |
| 3 | expanded PTFE gasket | 30″ | >5 min | 800° C. |

In the above text, a soft rubber o-ring made of silicone rubber is tested at room temperature, as a control, to verify that no other leaks are present in the apparatus. The leak back rate obtained indicates that there are no other possible sources for a leak in the chamber. Thus, the source of any leak could only be the seal at the flange. However, silicone rubber O-rings are generally not used during actual processing due to the high temperatures.

The results of the test indicate that the seal using the expanded PTFE Gasket was significantly stronger than the seal formed with the TEFLON®/TURCITE®O-ring, as the leak back rate of the expanded PTFE gasket exceeded the minimum specifications indicated by the manufacturer by a significant margin. In contrast, the seal using the TEFLON®/TURCITE® O-ring failed to meet even the minimum threshold set by the manufacturer.

In practical terms, the temperature resistance of the seal formed using the expanded PTFE gasket eliminates the problem of outgassing associated with conventional seal materials. Thus, furnace downtime, required to clean the apparatus after outgassing occurs, can be avoided. In addition, using expanded PTFE gaskets will also allow the use of oxidations with, for example, HCl for furnace cleaning without raising concerns of leakage of the oxidizing agent past the door seal and causing corrosion of the furnace framework in the area surrounding the door seal.

This invention provides seals using gaskets made of expanded polytetrafluoroethylene (PTFE). The present invention relates to a sealing assembly that seals a flange contact portion of a process container against a flange contact portion of a cap that is fitted to close the interior of the process container. The seal may be used in various heat treatment applications in the production of semiconductor wafers.

The gasket material of the present invention provides significant improvements in the durability, longevity, chemical and thermal resistance, and ease in installation of gasket material for use in O-ring groove flanges. Another advantage of the present invention is its ability to provide a thick low creep, pure fluorocarbon sealant that can be formed into a variety of gasket shapes and sizes. This provides far more utility and flexibility over many previous fluoro-rubber gaskets that required cutting from a sheet. While the present invention is somewhat similar to fluorocarbon joint sealant in its moldability, it has significantly better creep properties and higher maintained stresses with thick cross-section gaskets. As a pre-formed gasket, the present invention also eliminates positioning and mis-installation problems.

While this invention has been described in conjunction with the specific embodiments described above, it is evident that many alternatives, modifications and preferred embodiments of this invention as set forth above are intended to be illustrative and not limiting. Various changes can be made without departing from the spirit and scope of this invention as a defined in the following claims.

What is claimed is:

1. A semiconductor heat treatment apparatus comprising an interface between a first part and a second part, separated by an expanded PTFE gasket, wherein the gasket maintains a seal between the first and second parts.

2. The semiconductor beat treatment apparatus according to claim 1, wherein the first part and second part are made of quartz.

3. The semiconductor heat treatment apparatus according to claim 1, wherein the heat treatment apparatus is an atmospheric heat treatment apparatus.

4. The semiconductor heat treatment apparatus according to claim 1, wherein the heat treatment apparatus is at least one of an oxidation, diffusion, chemical vapor deposition or annealing furnace.

5. The semiconductor heat treatment apparatus according to claim 1, wherein the apparatus is vertically oriented and the seal is maintained by an upward pressure on the second part against the gasket and the first part.

6. The semiconductor heat treatment apparatus according to claim 1, wherein the apparatus further comprises a cooling mechanism to cool the gasket, the cooling mechanism comprising
a first cooling water passage formed within the second part, and
a second cooling water passage formed within a holding member attached to the first part.

7. A semiconductor heat treatment apparatus comprising:
a reaction tube having a closed end and an open end, wherein the open end is surrounded by a first flange;
a cap that closes the open end of the reaction tube, wherein the edge of the cap is surrounded by a second flange; and
a seal assembly comprising an expanded PTFE gasket placed between the first flange and the second flange, wherein the seal is maintained by placing the first flange and second flange against the gasket.

8. The semiconductor heat treatment apparatus according to claim 7, wherein the reaction tube and the cap are made of quartz.

9. The semiconductor heat treatment apparatus according to claim 7, wherein the heat treatment apparatus is an atmospheric heat treatment apparatus.

10. The semiconductor heat treatment apparatus according to claim 7, wherein the heat treatment apparatus is at least one of an oxidation, diffusion, chemical vapor deposition or annealing furnace.

11. The semiconductor heat treatment apparatus according to claim 7, wherein the apparatus is vertically oriented and the seal with the first flange is maintained by an upward pressure of the second flange against the gasket.

12. The semiconductor heat treatment apparatus according to claim 7, wherein the apparatus further comprises a cooling mechanism to cool the gasket, the cooling mechanism comprising
a first cooling water passage formed as a circumferential ring in the cap, and
a second cooling water passage formed as a ring in a holding member attached to the first flange.

13. A method of sealing a semiconductor heat treatment apparatus comprising:
placing an expanded PTFE gasket between a first part of the apparatus and a second part of the apparatus; and
bringing the gasket in contact with the first part and second part of the apparatus, whereby a seal is formed between the first and second parts by way of the gasket.

14. The method according to claim 13, wherein the reaction tube and cap are made of quartz.

15. The method according to claim 13, wherein the heat treatment apparatus is an atmospheric heat treatment apparatus.

16. The method according to claim 13, wherein the heat treatment apparatus is at least one of an oxidation, diffusion, chemical vapor deposition or annealing furnace.

17. The method according to claim 13, wherein the method further comprises cooling the gasket during the heat treatment process by
passing cooling water through a first cooling water passage formed as a circumferential ring in the cap; and
passing cooling water through a second cooling water passage formed as a ring in a holding member attached to the first flange to cool the gasket during a heat treatment process.

18. A method of sealing a semiconductor heat treatment apparatus comprising:
placing an expanded PTFE gasket between a first flange portion of a reaction tube and a second flange portion of a cap, wherein the gasket lies on the second flange portion; and
bringing the gasket in contact with the first flange portion by placing the cap against the reaction tube, whereby a seal is formed between the first and second flange portions by way of the gasket.

19. The method according to claim 18, wherein the reaction tube and cap are made of quartz.

20. The method according to claim 18, wherein the heat treatment apparatus is an atmospheric heat treatment apparatus.

21. The method according to claim 18, wherein the heat treatment apparatus is at least one of an oxidation, diffusion, chemical vapor deposition or annealing furnace.

22. The method according to claim 18, wherein the method further comprises cooling the gasket during the heat treatment process by
passing cooling water through a first cooling water passage formed as a circumferential ring in the cap; and
passing cooling water through a second cooling water passage formed as a ring in a holding member attached to the first flange to cool the gasket during a heat treatment process.
